(19) United States
(12) Patent Application Publication
(10) Pub. No.: US 2009/0276169 A1
(43) Pub. Date: Nov. 5, 2009

(54) Methods and Systems for Detecting, Localizing, Imaging and Estimating Ferromagnetic and/or Electrically Conducting Objects

(75) Inventors: David O. Walsh, Mukilteo, WA (US); William F. Avrin, San Diego, CA (US)

Correspondence Address: HOLLAND & HART, LLP, P.O BOX 8749, DENVER, CO, 80201, US

(73) Assignee: VISTA CLARA, INC., Everett, WA (US)

(21) Appl. No.: 12/418,329

(22) Filed: Apr. 3, 2009

Related U.S. Application Data
(60) Provisional application No. 61/042,655, filed on Apr. 4, 2008.

(51) Int. Cl. G01R 33/00; G06F 17/16; G06F 19/00

(52) U.S. Cl. 702/57; 324/200; 708/441

(57) ABSTRACT

Methods and systems for a universally applicable, linear, signal processing framework for optimal detection, localization, and feature extraction of dipolar magnetic and electromagnetic (EM) targets. Such methods and systems provide the ability to, for example, simultaneously and optimally solve the problems of detection, localization and estimation of the dipole vector or target response matrix; be applicable to different types of magnetic or EMI sensor system; and be applicable to arbitrary combinations of sensor locations and orientations, and arbitrary spatial sampling. Such functionality is provided, in various aspects of the disclosure, with a quadrature matched filter algorithm for detecting and imaging magnetic dipoles to the more complex realm of single- and multi-channel EMI sensors.

### CROSS-REFERENCE TO RELATED APPLICATIONS

This application claims priority to U.S. Provisional Patent Application No. 61/042,655, filed on Apr. 4, 2008, entitled “Detecting, localizing, imaging and estimating ferromagnetic and/or electrically conducting objects using electromagnetic sensors,” the entire disclosure of which is incorporated herein by reference.

### FIELD

The present disclosure is directed to detecting, localizing and discriminating of dipolar magnetic and electromagnetic (EM) targets using magnetic and/or electromagnetic sensors.

### BACKGROUND

The field of magnetic and EMI-based detection is lacking a single, universally applicable, optimal linear framework for detecting, localizing and extracting the key classification features of ferrous and non-ferrous conductors. The absence of such an algorithm has led to the development of a variety of sub-optimal, often non-linear algorithms that are typically applicable only to a restricted class of sensors and measurement conditions. The absence of a universally accepted optimal linear processing framework continues to drain limited R&D funds into duplicative R&D signal processing projects that produce algorithms that address only a small subset of the problem.

The development of algorithms for localizing and estimating static magnetic dipoles from passive magnetic field measurements dates to at least the early 1970's. Early algorithms were restricted to the problem of obtaining the bearing and dipole orientation using a single measurement of the magnetic gradient tensor. This approach required nonlinear processing and produced ambiguous (non-unique) results. The Frahm-Wynn approach was later extended to operate on two or more successive measurements of the magnetic gradient tensor, which eliminated ambiguities in the dipole location estimate, but was restricted to linear constant velocity sampling of the magnetic gradient tensor and used non-linear signal processing.

Two commonly used sensors for UXO surveys are active EM systems and passive magnetometers. UXO surveys utilizing such sensors are typically conducted by sampling the EM sensor response and/or the static magnetic field perturbation along a one-dimensional line, or along a two-dimensional grid close to the surface of the earth. However, a fundamental problem in UXO surveys is how to process the spatially sampled sensor response(s) so as to optimally detect, localize and discriminate UXO-like targets.

### SUMMARY

Provided in the present disclosure are methods and systems for a universally applicable, linear, signal processing framework for optimal detection, localization, and feature extraction of dipolar magnetic and electromagnetic (EM) targets. Such methods and systems provide the ability to, for example, simultaneously and optimally solve the problems of detection, localization and estimation of the dipole vector or target response matrix; be applicable to different types of magnetic or EMI sensor system; and be applicable to arbitrary combinations of sensor locations and orientations, and arbitrary spatial sampling. Such functionality is provided, in various aspects of the disclosure, with a quadrature matched filter algorithm for detecting and imaging magnetic dipoles to the more complex realm of single- and multi-channel EMI sensors.

Aspects of the disclosure may be implemented to, for example, address the problem of detecting, localizing and discriminating unexploded ordnance (UXO), using combinations of passive and/or active magnetic and/or electromagnetic sensors.

Aspects of the disclosure provide a quadrature matched filter (QMF) algorithm to detect, localize and estimate magnetic dipoles from an arbitrary array of magnetic field measurements. The QMF algorithm reduces the problem of estimating the magnetic dipole response at a given location to projecting the measured B-field data onto 3 ortho-normal basis functions that span the N-dimensional measurement space. This linear projection procedure, which is analogous to quadrature (i.e. FFT) detection of sinusoids of unknown phase, eliminates the need to exhaustively search over all possible combinations of dipole position and orientation and magnitude, and simultaneously provides optimal detection and unbiased estimation of the position and moment of an isolated dipole.

Aspects of the disclosure also provide a single solution to the entire critical post-processing chain for converting raw magnetic or EMI sensor data into estimates of individual dipolar targets, including their locations, orientations and dipole moments or target response matrices. This provides enhanced evaluation and field application of existing UXO sensors, and catalyzes the development of advanced multi-mode UXO detection sensors and discrimination algorithms.

### BRIEF DESCRIPTION OF THE DRAWINGS

FIG. 1 is an illustration of an electrically conducting or ferromagnetic object in a magnetic field;

FIG. 2 is an illustration of detected magnetic fields of an embodiment;

FIG. 3 is an illustration of detected magnetic fields of an embodiment; and

FIG. 4 is a block diagram illustration of a system of an embodiment.

### DESCRIPTION

Aspects of the present disclosure address the problem of detection, localization and characterization of magnetic dipole sources based on an array of vector EMI and/or passive magnetic-field (B-field) measurements at arbitrary locations and orientations. Embodiments are described that use a linear, all-mode magnetic source detection, localization and feature extraction algorithm for active and passive magnetics-based UXO detection and discrimination. In an embodiment, this is accomplished based on a quadrature matched filter (QMF) algorithm that operates on single and multi channel EM induction sensors.

As described above, two commonly used sensors for UXO surveys are active EM systems and passive magnetometers. UXO surveys are typically conducted by sampling the EM sensor response and/or the static magnetic field perturbation along a one-dimensional line, or along a two-dimensional grid close to the surface of the earth. Hence, a fundamental problem in UXO surveys is to process the spatially sampled sensor response(s) so as to optimally detect, localize and discriminate UXO-like targets.

Static magnetic targets are commonly modeled to a first order as combinations of co-located magnetic dipole moments. Ferrous UXO targets, including most artillery shells, generally exhibit both a remnant dipole moment and an induced dipole moment produced by their response to an applied magnetic field or to the ambient earth's magnetic field. For a static UXO target in the earth's magnetic field, the remnant and induced moments combine to produce a single vector dipole moment m with magnitude |m|.

Active EM systems of an embodiment apply time-dependent magnetic fields, to induce transient or alternating magnetic dipole responses in the target. These responses come about in two main ways. First, the ferrous material in the target can become magnetized in response to the applied field. In addition, time-dependent applied fields induce eddy current loops in electrical conductors, and these eddy currents in turn produce transient or AC dipole moments along one or more axes of the target. For a target made of ferrous metal, these two effects combine to create a frequency-dependent magnetic dipole response. This response depends on the composition, size, shape and orientation of the target, as well as the orientation of the applied magnetic field with respect to the target.

In one embodiment, a solution to this problem is provided for the case of a target whose response is defined by a static magnetic dipole, which may be extended to the case of active EM detection. The method of this embodiment is based on linear correlation, or matched filtering. Methods of such an embodiment shares mathematical properties of optimal detection, unbiased estimation and relatively efficient computation.

The mathematical framework in an embodiment of the Quadrature Matched Filter algorithm for localizing and characterizing targets based on their response to an applied electromagnetic field is now discussed. This discussion has three parts. First, definition of a frequency-dependent target response matrix, which describes the relationship between the applied magnetic field and the magnetic moment that is induced in the target. Second, localization technique, which in an embodiment uses least-squares optimization to find the target location and target response matrix that explain the magnetic-field response that we measure. Third, an embodiment is described that provides an efficient least-squares optimization that takes advantage of the fact that the magnetic dipole response is proportional to the target response matrix.

### Magnetic Dipole Response and Target Response Matrix

In this embodiment, a magnetic field is applied to a target according to:

\vec{B}(\vec{r})=[Bₓ(\vec{r}),B_{y}(\vec{r}),B_{z}(\vec{r})]^{T}, (1)

where \vec{r} is the position of the target in three dimensions, and x, y and z are three orthogonal directions in space. If the dimensions of the target are small compared with the distance from the target to the measured points of the magnetic field can be used to characterized the response of the target in terms of its induced magnetic moment

\vec{m}=[mₓ,m_{y},m_{z}]^{T}. (2)

For most targets, the induced magnetic moment is approximately proportional to the applied magnetic field. The relationship between the induced moment and the applied field can be described in terms of a matrix, that is

$$\begin{matrix}\vec{m} = M \cdot \vec{B} ( \vec{r} ) , \\ where & ( 3 ) \\ M = [ \begin{matrix}{M}_{xx} & {M}_{xy} & {M}_{xz} \\ {M}_{yx} & {M}_{yy} & {M}_{yz} \\ {M}_{zx} & {M}_{zy} & {M}_{zz}\end{matrix} ] . & ( 4 )\end{matrix}$$

and Mᵢⱼ is the magnetic moment in the i direction, due to an applied magnetic field in the j direction. M depends on the size, shape and composition of the target, its orientation in space, and the frequency of the applied magnetic field. In general, the elements of M are complex numbers, since the target's response has both a magnitude and a phase with respect to the applied field.

In general, if the applied magnetic field is allowed to vary over all possible orientations, the induced dipole moment would trace out an ellipsoid. The target's response can then be described by six numbers, three to define the directions of the principal axes of the ellipse, and three to describe the response to magnetic fields applied along each of these principal axes. In matrix language, M is Hermitian, with Mᵢⱼ=Mⱼᵢ*, so that it only has six independent components.

The eigenvalues of M, which describe the response of the target to magnetic fields along each of its principal axes, are characteristic of the target itself. The magnitudes and phases of these eigenvalues vary with frequency in ways that depend on the size, shape, composition and thickness of the target. Therefore, in this embodiment, classification is accomplished for an unknown target by determining M at a range of frequencies, calculating its eigenvalues, and comparing their frequency dependences to those of known objects. The next section describes the use of a matched-filter technique to determine both the response matrix and the position of a target for an embodiment.

### Matched Filter Technique for Locating and Characterizing a Target

In this embodiment, an EM measurement is conducted in which a characterization of the frequency-dependent response of targets is accomplished by applying magnetic fields at a range of frequencies and analyzing the resulting transient magnetic field response. In another embodiment, characterization of the frequency-dependent response of targets is accomplished by applying short pulses of magnetic field and analyzing the resulting transient magnetic field response. The following discussion describes the embodiment in which measurements are made at one frequency. The approach of this embodiment may be readily modified in other embodiments to include measurements at a range of frequencies, as will also be described.

Initially, a measurement of a set of N magnetic-field quantities Bⱼ is taken. Each of these measurements is made at a sensor position \vec{r}ⱼ and in a direction defined by the unit-length vector \hat{d}ᵢ. Each measurement is made with an applied magnetic field \vec{B}ⱼ^{A}(\vec{r}), whose orientation and variation with position depend on the location, orientation and geometry of the applied-field coil used for that measurement. In building this set of magnetic measurements, a range of source-coil locations or orientations may be used, to make sure that the target is exposed to magnetic fields in all three independent directions. The data from these measurements can be represented by a vector Bₘₑₐₛ that lies within a vector space of dimension N. Using these data, a target may be identified that is defined by its position r and its response matrix M. As discussed above, M has six independent components. Including the three independent components of the position vector \vec{r}, a total of nine independent quantities to define the target are needed to complete the matrix.

To determine these parameters, a calculation determines what the magnetic fields would be for various possible values of \vec{r} and M. The calculated fields, in this embodiment, are given by

$${B}_{j} = \frac{{μ}_{0}}{4 π} ( \frac{{\vec{m}}_{j} \cdot ( \vec{r} - {\vec{r}}_{j} ) {\hat{d}}_{j} ( \vec{r} - {\vec{r}}_{j} )}{{\vert \vec{r} - {\vec{r}}_{j} \vert}^{5}} - \frac{{\vec{m}}_{j} \cdot {\hat{d}}_{j}}{{\vert \vec{r} - {\vec{r}}_{j} \vert}^{3}} ) , \\ where \\ {\vec{m}}_{j} = M \cdot {\vec{B}}_{j} ( \vec{r} ) . \qquad ( 5 )$$

The goal is to find the values of \vec{r} and M that best match the measured magnetic fields. That is, these parameters are chosen so as to minimize the distance |Bₘₑₐₛ−B_{calc}| between the N-dimensional vectors representing the measured and calculated magnetic-field data. One method, of an embodiment, for determining these parameters is through stepping systematically through multiple values for each of the nine parameters required to specify r and M. In another embodiment, a method is used that provides a relatively simplified computation by taking advantage of the fact that the magnetic-field response at any given position is proportional to M.

For a given target position, if the response matrix is varied through all possible values, the resulting calculated data vectors B_{calc} will span a six-dimensional subspace within the N-dimensional space of all possible data vectors. From basic linear algebra, of all possible calculated data vectors within this subspace, the one that lies closest to the measured data vector Bₘₑₐₛ is Bₚᵣₒⱼ, the projection of Bₘₑₐₛ into this subspace.

To calculate that projection, a set of six orthonormal basis vectors uₖ are generated that span this subspace of possible calculated data vectors for a given target position. Then, for that target position, the smallest possible difference between the calculated and measured data vectors is given by

|δBₘᵢₙ|=|Bₘₑₐₛ−Bₚᵣₒⱼ|, with Bₚᵣₒⱼ=Σₖuₖ(uₖ·Bₘₑₐₛ) (6)

where the • here indicates the inner product of two Nₘₑₐₛ-dimensional data vectors.

By this projection technique, without explicitly searching through all possible values of the six parameters that define the target's response matrix, the method of this embodiment generates a minimum difference between measured and calculated data vectors for a given target position. At this point, this method steps through a mesh of possible target positions and finds the position that gives the smallest error. Thus, instead of searching through a nine-dimensional space of different r and M values, a search is only required that searches through the three-dimensional space of possible target positions. The method can also be restricted to searching though only a two-dimensional position space, or only a one-dimensional dimension space, or even a zero-dimensional position space where the object position is known only its response matrix M is unknown. The method can also be extended to include a search over the dimension of time, in addition to position.

Forming the Basis Vectors uₖ

To implement the strategy of this embodiment, a method for producing the orthonormal basis set uₖ that spans the 6-dimensional space of calculated data vectors for a given target position is provided. First a vector representing the six independent components of the target's response matrix M is constructed:

M=[M₁, . . . , M_{6Nf}]^{T}=[Mₓₓ,M_{yy},M_{zz},M_{xy},M_{xz},M_{yz}]^{T}. (7)

Next, a set of independent data vectors that span this six-dimensional subspace is formed. In this embodiment, the independent data vectors are generated by setting one of the Mᵢ equal to 1, setting the others to 0, and calculating the resulting data vector. Doing this for each of the Mᵢ creates a set of calculated data vectors bₙ, where n runs from one through six. These data vectors are not necessarily orthogonal to each other. However, in general, they are linearly independent and thus span the space of possible calculated data vectors for the target position being considered.

From these six linearly independent data vectors, the 6-by-6 matrix Nₙₘ=bₙ·bₘ is formed. At this point, the eigenvectors of this matrix are determined according to,

vₖ=[v₁ₖ, . . . v₆ₖ]^{T}, (8)

where k runs from one through six. The matrix Nₙₘ can be viewed as representing a linear transformation within the six-dimensional space of independent components of M. Its eigenvectors vₖ are orthogonal. These vectors are then normalized to all have unit length, thereby forming an orthonormal basis set within that six-dimensional space.

If each of the vₖ defines a particular combination of the six components of the target response matrix M, it corresponds to a calculated data vector given by

uₖ=Σₙvₙₖbₙ. (9)

Each of these data vectors has N components, and falls within the six-dimensional subspace of possible calculated data vectors for a given target position. Using the definition of Nₙₘ above, the fact that the vₖ are eigenvectors of Nₙₘ, and the orthogonality of the vₖ within their own six-dimensional space, it can be shown that the uₖ are also orthogonal as vectors within the N-dimensional space of data vectors. If the uₖ are normalized so that they have unit length, they then form an orthonormal basis set that spans the six-dimensional subspace of possible calculated data vectors for a given target position.

### Determining the Target Response Matrix:

As described above, embodiments may use the basis vectors uₖ to calculate the smallest possible difference between the measured and calculated data vectors for a given target position. Such embodiments can then vary the position to find the target location for which this difference is the lowest. Or in another embodiment, the target location can be found that maximizes the norm of the vector sum Bₚᵣₒⱼ=Σₖuₖ(uₖ·Bₘₑₐₛ). This is referred to as the norm of the projection of Bₘₑₐₛ onto the six-dimensional measurement space the dipole correlation function, and this is the quantity that is displayed in “3D correlation images” as will be described in additional detail below.

Once the best location is found according to the above, the corresponding best estimate of the target response matrix can be calculated. From the construction procedure above, each of the vk corresponds to a certain combination of values for the six components of the target response matrix. Each of the uₖ is the calculated data vector corresponding to that value of the target response matrix. Using this correspondence, and the orthogonality of both the vₖ (in the response-matrix space) and the uₖ (in the data space), for a given target position, the best estimate of the response matrix is given by

Mₙ=Σₖvₖ(uₖ·Bₘₑₐₛ). (10)

The uₖ, by the way they are constructed, are functions of the target position. By applying the equation above at the best-estimate target position, the best-estimate value of the target response matrix at that position is obtained.

### Generalization to Multiple Frequencies

As described above, other embodiments may use multiple frequencies that may be used to characterize the target more completely. This information may be derived by explicitly applying magnetic fields at a selection of frequencies, or by applying a pulse of magnetic field and analyzing the resulting transient response. The embodiments described above can be generalized in a straightforward way to handle such multiple-frequency measurements.

For example, each of the magnetic measurements Bⱼ may be repeated at N_{f} different frequencies. Then, the space of possible data vectors would increase in dimension by a factor of N_{f}. Because the target's response depends on frequency, 6N_{f} independent quantities would be needed to specify the target-response matrix M, that is, six independent components at each of the N_{f} frequencies. The subspace of possible calculated data vectors for a given target position would then have dimension 6N_{f} instead of six. Nₙₘ in Eq. (8) above would be a 6N_{f}×6N_{f} matrix, instead of a 6×6 matrix. However, since the measurements at different frequencies are independent of each other, Nₙₘ would be a block-diagonal matrix, with separate 6×6 blocks for each of the different frequencies. This embodiment may then find the eigenvectors of this matrix by repeating the procedure described above for each of these 6×6 blocks. The basic algorithm as described in the above embodiments for finding the best-fit target parameters could then be used as described above.

Specific QMF Algorithm Output Parameters may be used in various different embodiments for various applications. Table 1 provides several exemplary output parameters and practical applications:

TABLE 1

| QMF Output Parameter | Practical Application |
|---|---|
| 3D correlation image | Initial detection and 3D location of metallic or ferromagnetic |
| | objects via detection of local maxima in 3D correlation image, |
| | followed by thresholding |
| Target Dipole Response | Magnetometers: estimated 3 × 1 vector dipole moment for |
| | detected/localized targets (dipole magnitude and orientation) |
| | EMI sensors: estimated 3 × 3 EMI response matrix M for |
| | detected/localized targets (defines amplitude/phase response of |
| | target to applied field in any direction) |
| | Used as the basis for UXO classification and discrimination. |
| Residual: \|Bₘₑₐₛ − B_{calc}\| | Direct measure of how well the estimated target(s) fits the |
| Bₘₑₐₛ minus the projection of | assumed model of an isolated dipole source(s). Can be used to |
| estimated dipole or EMI target | identify non-dipolar targets, and/or overlapping dipole |
| response onto data space | signatures. The QMF algorithm can be applied to residual data |
| | to detect smaller secondary dipole targets that were previously |
| | obscured by the first detected target. |

### Advantages of the QMF Algorithm

Key mathematical and practical advantages of the QMF algorithm include:
Optimal detection of an isolated magnetic dipole at a hypothesized position.
Unbiased location estimates of isolated dipoles.
Direct unbiased estimation of static and EM-induced dipole moments and orientations.
Applicable to both vector magnetic field measurements and EMI sensors. Passive total field measurements may be equivalently processed as differential vector magnetic fields, measured in the direction of the Earth's magnetic field.
No restriction on the number, orientation, location and operating frequency of transmitting and sensing elements. Note that the derivation makes no assumptions of the number, location or orientation of sensors, or the number, locations or orientations of targets. The only assumption is that the nature of the magnetic or EMI source(s) is dipolar.
Linear, forward computation.
   no ill-conditioned or non-linear inversions
   no starting guesses or blind-alley iterations
   suitable for recursive and/or parallel computation.
Residual provides measure of confidence for isolated dipole assumption.
Orthogonal basis functions provide direct measure of sensitivity of measurement array to target locations and orientations. The basis functions in the dipole and measurement spaces are a by-product of the QMF algorithm, and they provide a direct measure of the sensitivity of the measurement array to each of the three possible dipole orientations at each target location, or six independent target responses in the case of an EMI sensor. This can be used to optimize EMI sensor design, and optimize measurement planning and spatial sampling for a particular sensor design.

Unbiased localization is important because a small error in location or position can produce a much larger error in the estimated target moment or induced AC moments. For passive sensing, the measured magnetic field is proportional to 1/(rangê3), and for active systems the magnetic field is proportional to 1/(rangê6). So a location error of +/−20% can lead to an estimated induced moment error of +/−300%.

In one embodiment, the quadrature matched filtering approach in active EMI surveys is employed. The EMI sensor may be a single channel EMI metal detector with coincident transmit and receive coil. The transmit/receive antenna, in this embodiment, is a single circular wire loop of diameter 0.5 m, with its axis normal to the surface of the Earth. The sensor is moved laterally above the surface of the Earth, sampling the induced amplitude response from coincident transmit/receive coil locations across a 10 m×10 m grid of survey points, with a regular sampling interval of 0.5 m. The quadrature matched filter algorithm may be computed and applied over a 3-D grid spanning the volume x=(−5 m: 0.25 m:+5 m), y=(−5 m: 0.25 m:+5 m), z=(−3 m: 0.25 m:0 m).

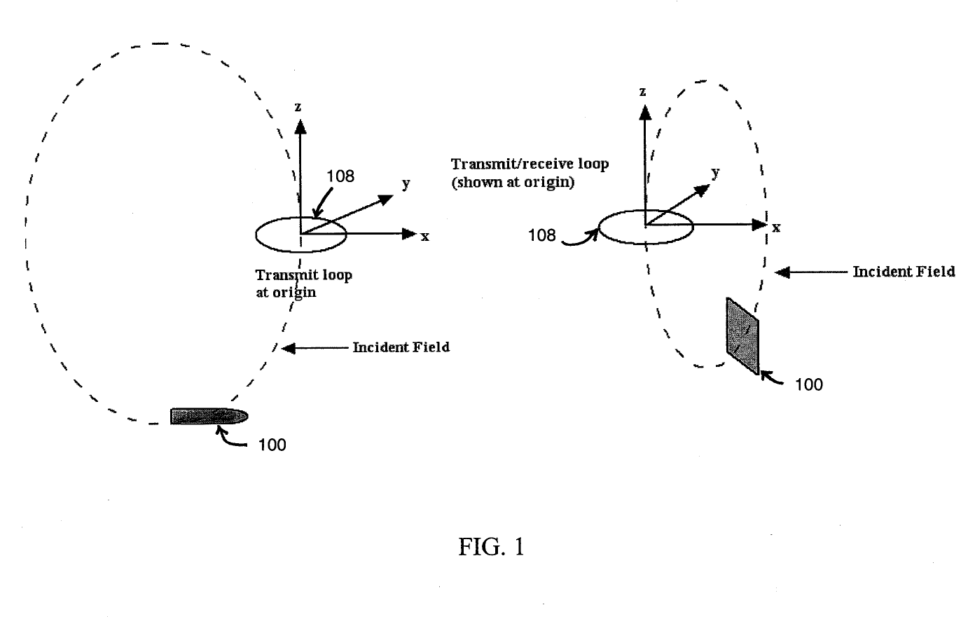

The forward responses may be computed for two dissimilar objects, such as depicted in FIG. 1. The first object 100, on the left in FIG. 1, is analogous to an intact unexploded artillery shell. This first object 100, the UXO target, may be located at position {x,y,z}={−1, 0, −2}, with its principle response axis oriented in the x-direction with respect to coil 108, as illustrated in FIG. 1. The second object 104, shown on the right in FIG. 1, is analogous to a flat conducting plate. This second object 104 may be considered to be a clutter object, and in the illustration of FIG. 1 is located at position {x,y,z}={1, 0.5, −1.25} with respect to coil 108. The second object 104, the flat conducting plate, responds to an incident field along a single axis that lies in the x-y plane, at an angle of 45 degrees from the x-axis. The EMI target response matrices for the modeled UXO and clutter objects are (in {x,y,z} coordinates):

$${M}_{UXO} = [ \begin{matrix}3 & 0 & 0 \\ 0 & 1 & 0 \\ 0 & 0 & 1\end{matrix} ] , {M}_{clutter} = [ \begin{matrix}.5 & .5 & 0 \\ .5 & .5 & 0 \\ 0 & 0 & 0\end{matrix} ] . \qquad ( 11 )$$

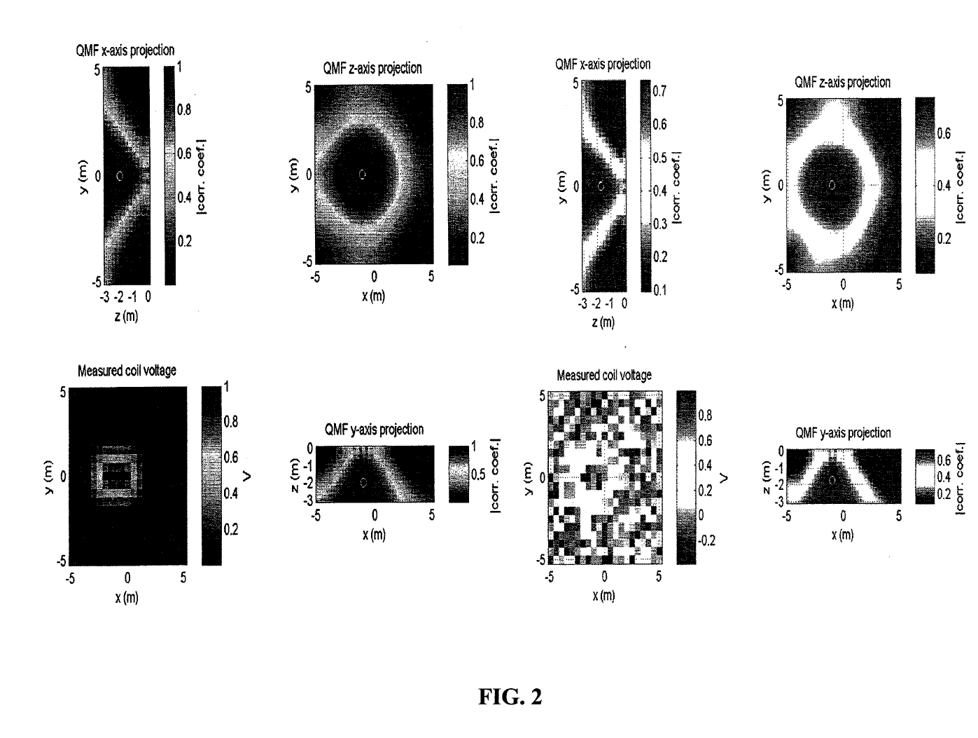

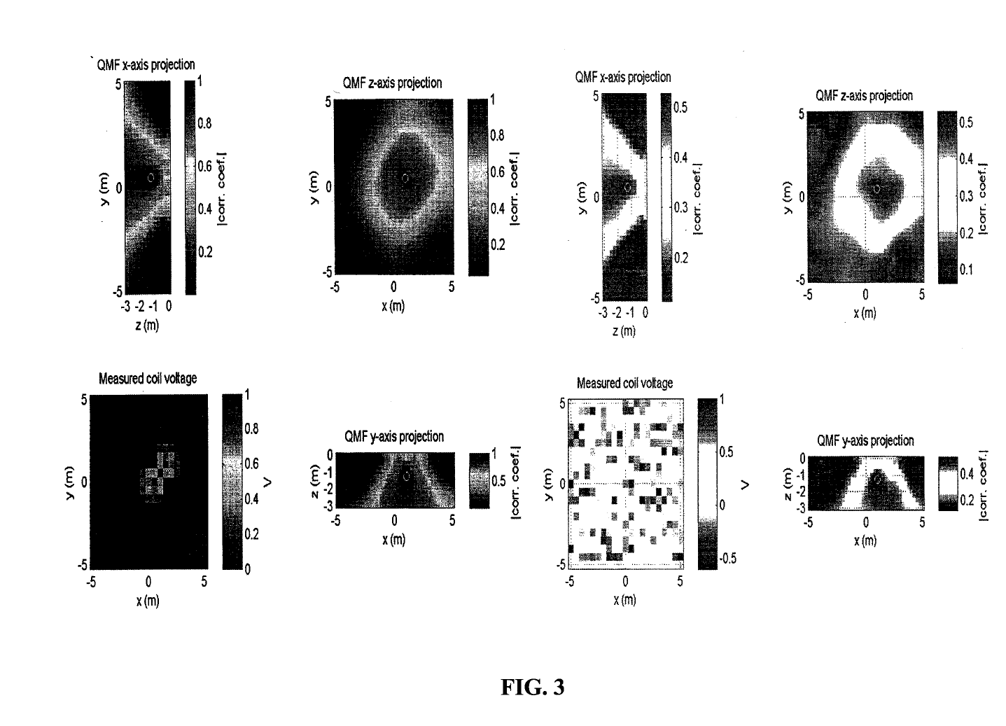

In an embodiment, computer simulations are performed for each object separately, first with no measurement noise, and then with white Gaussian noise samples added to produce a peak signal to noise ratio (PSNR) of 5. The measured coil voltages and maximum magnitude projections of the QMF-generated 3D correlation maps, are shown for the UXO object and the clutter object in FIGS. 2 and 3, respectively. Note that the QMF-generated correlation maps of this embodiment are only slightly distorted by the addition of a significant level of measurement noise.

In the absence of measurement noise, the QMF algorithm of this embodiment located the 3D position of each object with zero or near zero error, and estimated the target EMI response matrix of each object with zero or near zero error. After the addition of noise, the QMF algorithm located the position of the UXO object with an error of +0.25 m in the z-dimension, and located the clutter object with zero or near zero error (interpret as: location error <0.25 m volume sampling resolution). The QMF-estimated EMI target response matrices using the noisy data for the UXO and clutter targets are:

$${\hat{M}}_{UXO} = [ \begin{matrix}1.84 & - .08 & - .01 \\ - .08 & .73 & - .02 \\ - .01 & - .02 & .52\end{matrix} ] , {\hat{M}}_{clutter} = [ \begin{matrix}.33 & .57 & .03 \\ .57 & .46 & .02 \\ .03 & .02 & .06\end{matrix} ] . \qquad ( 12 )$$

These QMF-estimated target response matrices look like noisy versions of the actual target response matrices in eq. (11). The estimated UXO matrix \hat{M}_{UXO} also appears to be scaled by a factor of approximately 0.62, compared to the actual UXO target response \hat{M}. This is attributed to the underestimation of the depth of the UXO object (1.75 m vs. actual depth of 2.0 m), and highlights the importance of accurate and unbiased localization.

With respect to Spatial Resolution, it is noted that the QMF algorithm is an optimal detector and unbiased estimator of the location and dipole response of an isolated dipolar target. However, the QMF algorithm is not a “super-resolution” algorithm. Its ability to spatially resolve individual targets hinges on the individual target responses being sufficiently de-correlated in the measured data space. The spatial resolution for the QMF-EMI algorithm in particular depends on many factors including the lateral separation of the targets, the depth of the targets, the relative sizes of the targets (large targets can easily obscure smaller ones), and also the number, geometry, and spatial sampling orientation of the EMI measurements.

Standard analytical and statistical methods may be used to determine optimality and assess the effects of various measurement errors for a particular system and application, as will be readily understood by one of skill in the art. Extensive and detailed computer simulations also may be used to support analytical efforts and results.

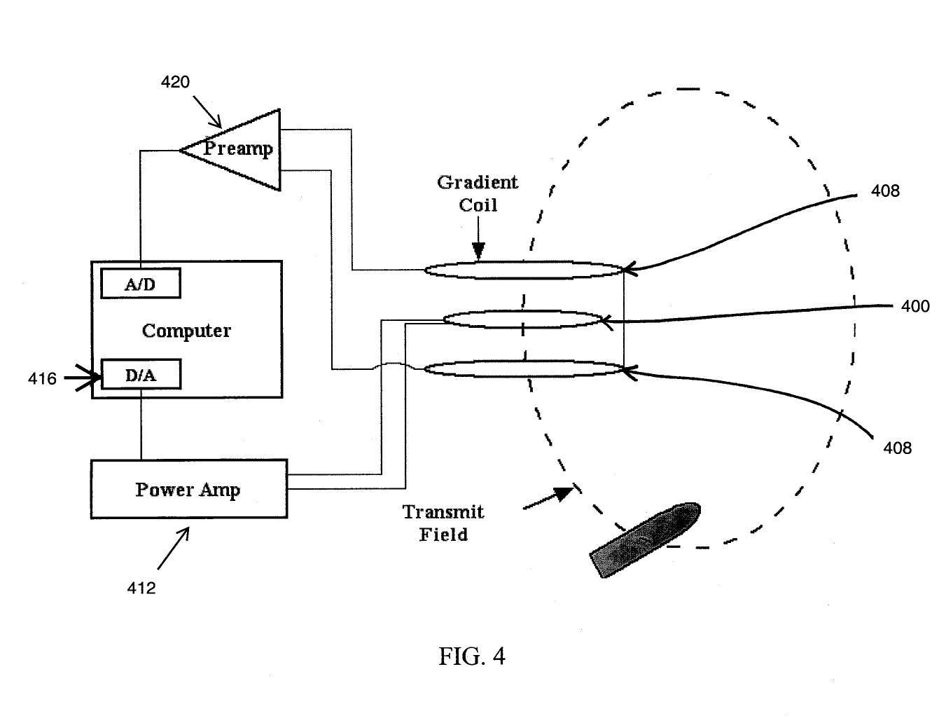

EMI systems as described may have several different configurations, such as illustrated in FIG. 4. In this embodiment, a single transmit coil 400 transmits CW waveforms, and a computer 404 simultaneously records the voltage on a single balanced gradient coil 408 that is designed to have minimal sensitivity to the transmit coil B-field. The computer 404 includes processing hardware, such as analog-to-digital (A/D) and digital-to-analog (D/A) converters, that may be integrated into processing modules or that may be separate components from other processing modules and/or communications modules that may be present in computer 408. In this embodiment, the computer 404 generates a CW waveform on transmit coil 400 through a power amplifier 412 that receives output of a D/A converter 416. The gradient coil 408 provides an output to a preamplifier circuit 420 that amplifies the signal received at the gradient coil 408 and provides the amplified signal to an A/D converter 420 in computer 404. While a single channel is illustrated in FIG. 4, it will be understood that multi-channel systems may be implemented in a similar manner.

The EMI data, in an embodiment, is collected using a low-field NMR spectrometer system that may be included in computer 404 of the embodiment of FIG. 4. Such a spectrometer, in an embodiment, includes a PCI computer with PCI data acquisition cards for high-speed analog output and multi-channel 24-bit A/Ds with simultaneous sampling up to 102.4 kHz, a 2000 W audio power amplifier, and custom multi-channel pre-amp and receive electronics. Software is used, in this embodiment, to generate CW fields and simultaneously record the EMI response.

A significant issue in these types of measurements is fluctuations in the direct signal, which can be caused by fluctuations in current in applied field coils, electronics stability, geometric instability, etc. This embodiment uses a balanced gradiometer coil for the sense coil to eliminate a significant portion of the direct signal. In order to initially calibrate the system, EMI measurements are taken with no targets present, to estimate and subtract the transmit B-field leakage and any induced responses from other conductors in the vicinity.

Robust detection, localization and feature extraction in typical field applications may be obtained by applying the EMI-QMF algorithm to data collected during field tests, for example. In one embodiment, software is provided to model the physics of each specific sensor, in order to generate accurate models for the incident and received fields. Sensor-specific code may be employed to read and precondition the raw sensor data, and generate an appropriate time- or frequency-domain output for follow-on discrimination.

Such software may be a stand-alone software package or a software package that can be bundled with OEM manufacturers equipment, for example. In one embodiment, the software package is a Windows executable software program to process data from several common commercial UXO sensors, using the QMF algorithm to detect, localize and extract magnetic dipoles and/or target response matrices. Such a software package may include a graphical user interface for importing, processing, and visualizing magnetic and EMI sensor data; ability to directly import and process data from all commercial sensors included in the field test data; export of estimated target locations, estimated target response matrices, and residual measures for estimating confidence in the results.

The process, in various embodiments, may be used in the problem of improvised explosive devices (IED's). In one embodiment, a vehicle-mounted magnetic tensor gradiometer system for detecting and localizing IED's in real time may be assembled. This system uses the QMF algorithm for detecting and localizing both in-road and roadside IED's, and discriminating IED signatures from common clutter objects such as underground pipes and non-threatening ferrous objects.

In one embodiment, the system includes four high-precision custom EMI coils for EMI data collections. In this embodiment, each Tx/Rx coil has a transmit coil in the center, surrounded by a 2-piece gradient coil, with precision coil windings to minimize pickup of the direct transmit field. Each coil is wound on a custom Delrin (plastic) core.

What is claimed is:

1. A method for detecting a ferromagnetic or electrically conducting target object, comprising:
providing one or more magnetic field transmitting devices and one or more magnetic field receiving devices;
using each of said transmit devices to generate a magnetic field applied to a target according to:
\vec{B}(\vec{r})=[Bₓ(\vec{r}),B_{y}(\vec{r}),B_{z}(\vec{r})]^{T},
where \vec{r} is the position of the target in three dimensions, and x, y and z are three orthogonal directions in space;
using each of said receiving devices to record the magnetic field that is generated by the target response;
arranging the set of said recorded magnetic field measurements as a vector Bₘₑₐₛ that lies within a vector space of dimension N;
selecting a hypothetical dipole source position;
calculating a set of six orthonormal basis vectors uₖ that span the subspace of possible calculated data vectors for the selected dipole source position;
calculating an estimate of the target response vector M as Mₙ=Σₖvₙₖ(uₖ·Bₘₑₐₛ) where k runs from 1 through 6 and vₖ=[v₁ₖ, . . . , v₆ₖ]^{T} are a set of 6 orthogonal or orthonormal basis vectors that span the 6-dimensional subspace of possible solutions to the target response vector M.

2. The method of claim 1, wherein a plurality of hypothetical target locations are selected, and where a target position is estimated as the location that produces a global maximum or local maximum of the vector sum Bₚᵣₒⱼ=τₖuₖ (uₖ·Bₘₑₐₛ).

3. The method according to claim 1, wherein a plurality of target response measurements are obtained by moving a reduced number of said physical transmitting devices and/or said physical receiving devices though different positions in space, and processing the data as if the measurements were obtained using a larger number of physical transmitting devices and/or receiving devices located at different locations in space.
